(19) United States
(12) Patent Application Publication
(10) Pub. No.: US 2012/0286976 A1
(43) Pub. Date: Nov. 15, 2012

(54) ILLUMINATED KEYBOARD

(75) Inventor: Chung-Yuan Chen, Taipei (TW)

(73) Assignee: PRIMAX ELECTRONICS LTD., Taipei (TW)

(21) Appl. No.: 13/159,647

(22) Filed: Jun. 14, 2011

(30) Foreign Application Priority Data
May 13, 2011 (TW) 100116783

(51) Int. Cl. H03M 11/00

(52) U.S. Cl. 341/22

(57) ABSTRACT

An illuminated keyboard includes plural keys, a membrane switch circuit member, an illumination module for emitting light beams, and a light-shading layer. When the membrane switch circuit member is triggered by one of the keys, a corresponding key signal is generated. The light-shading layer is used for sheltering the light beams. The light-shading layer is disposed on the membrane switch circuit member. The side of the light-shading layer closer to the illumination module has a relatively higher light-shading percentage. As a consequence, the keys of the illuminated keyboard can be uniformly illuminated.

### FIELD OF THE INVENTION

The present invention relates to a keyboard, and more particularly to an illuminated keyboard with an illuminating function.

### BACKGROUND OF THE INVENTION

A keyboard is one of the widely-used computer peripheral devices. Via the keyboard, the user may input characters and instructions into a computer. FIG. 1 is a schematic top view illustrating the outward appearance of a conventional keyboard. The surface of the conventional keyboard 1 includes plural keys. These keys 10 are classified into several types, e.g. ordinary keys 101, numeric keys 102 and function keys 103. When one or more keys are depressed by a user, a corresponding signal is issued to the computer, and thus the computer executes a function corresponding to the depressed key or keys. For example, when an ordinary key 101 is depressed, a corresponding English letter or symbol is inputted into the computer. When a numeric key 102 is depressed, a corresponding number is inputted into the computer. In addition, the function keys 103 (F1˜F12) can be programmed to cause corresponding application programs to provide certain functions. Moreover, one of the ordinary key 101 is a space bar 1011. The space bar 1011 is arranged at a first side of the conventional keyboard 1. Whereas, the function keys 103 are arranged at a second side of the conventional keyboard 1.

With the maturity of the computing technologies, the conventional keyboard that has basic functions fails to meet the requirements of various users. For this reason, the keyboard manufacturers make efforts in designing novel keyboards with diversified functions. Recently, an illuminated keyboard with an illuminating function has been disclosed. Since the outward appearance of the conventional illuminated keyboard is similar to the outward appearance of the conventional keyboard 1, only the inner structure of the conventional illuminated keyboard will be illustrated in more details as follows.

FIG. 2 is a schematic cross-sectional view illustrating a conventional illuminated keyboard. As shown in FIG. 2, the illuminated keyboard 2 comprises plural keys 20, a membrane switch circuit member 21, a light guide plate 22, an illumination module 23, a main circuit board 24, a reflector 25 and a base plate 26. The key 20 comprises a keycap 201, a key housing 202 and an elastic element 203. From top to bottom, the keycap 201, the key housing 202, the elastic element 203, the membrane switch circuit member 21, the light guide plate 22, the reflector 25 and the base plate 26 of the conventional illuminated keyboard 2 are sequentially shown. The illumination module 23 is arranged at a first side of the membrane switch circuit member 21. The main circuit board 24 is arranged at a second side of the membrane switch circuit member 21.

In the key 20, the keycap 201 is exposed outside the surface of the illuminated keyboard 2, so that the keycap 201 can be depressed by the user. The key housing 202 is used for fixing the keycap 201 and the elastic element 203. The elastic element 203 is penetrated through the key housing 202. In addition, both ends of the elastic element 203 are contacted with the keycap 201 and the membrane switch circuit member 21, respectively. The membrane switch circuit member 21 comprises an upper wiring board 211, a partition plate 212 and a lower wiring board 213. The upper wiring board 211, the partition plate 212 and the lower wiring board 213 are made of a transparent material. The transparent material includes for example polycarbonate (PC) or polyethylene (PE). The upper wiring board 211 has plural upper contacts 2111. The partition plate 212 is disposed under the upper wiring board 211, and comprises plural partition plate openings 2121 corresponding to the plural upper contacts 2111. The lower wiring board 213 is disposed under the partition plate 212, and comprises plural lower contacts 2131 corresponding to the plural upper contacts 2111. The plural lower contacts 2131 and the plural upper contacts 2111 are collectively defined as plural key intersections. Moreover, the membrane switch circuit member 21 is connected with the main circuit board 24 for transmitting first electric power and signals.

The illumination module 23 comprises an illumination circuit board 231 and plural light emitting diodes 232. For clarification and brevity, only a light emitting diode 232 is shown in the drawing. The illumination circuit board 231 is arranged at the first side of the membrane switch circuit member 21 for providing second electric power to the plural light emitting diodes 232. The plural light emitting diodes 232 are mounted on the illumination circuit board 231. By acquiring the second electric power, the plural light emitting diodes 232 are enabled to emit plural light beams. By the light guide plate 22, the plural light beams are guided to the keycaps 201. As shown in FIG. 2, the reflector 25 is disposed under the light guide plate 22 for reflecting the light beams. The base plate 26 is disposed under the reflector 25 for supporting the keycap 201, the key housing 202, the elastic element 203, the membrane switch circuit member 21, the light guide plate 22 and the reflector 25.

In the conventional illuminated keyboard 2, the keycap 201 has a light-transmissible region 2011. The light-transmissible region 2011 is located at a character region or a symbol region of the keycap 201. Moreover, the position of the light-transmissible region 2011 is aligned with a corresponding light-guiding zone 221 of the light guide plate 22. In such way, the light beams can be guided to the light-transmissible region 2011 through the light-guiding dots 2211 of the light-guiding zone 221, thereby illuminating the character region or the symbol region of the keycap 201. Consequently, the illuminating efficacy is achieved.

The conventional illuminated keyboard, however, still has some drawbacks. For example, since the illumination circuit board 231 is arranged at the first side of the membrane switch circuit member 21, the amount of light beams passing through the side of the illuminated keyboard 2 close to the space bar (see FIG. 1) is relatively higher. Whereas, the amount of light beams passing through the side of the illuminated keyboard 2 distant from the space bar is relatively lower. Under this circumstance, the keys of the conventional illuminated keyboard 2 fail to be uniformly illuminated.

### SUMMARY OF THE INVENTION

The present invention relates to an illuminated keyboard with a uniform illuminating efficacy.

In accordance with an aspect of the present invention, there is provided an illuminated keyboard. The illuminated keyboard includes plural keys, a membrane switch circuit member and a light-shading layer. The membrane switch circuit member has plural key intersections corresponding to respective keys. The illumination module is arranged at a first side of the membrane switch circuit member for emitting plural light beams. The light-shading layer is disposed under the plural keys for sheltering the plural light beams. A first side of the light-shading layer has a higher light-shading percentage than a second side of the light-shading layer. In addition, the first side of the light-shading layer is closer to the illumination module than the second side of the light-shading layer.

In an embodiment, the membrane switch circuit member includes an upper wiring board, a partition plate and a lower wiring board. The upper wiring board has plural upper contacts. The partition plate is disposed under the upper wiring board, and has plural partition plate openings corresponding to the plural upper contacts. When the membrane switch circuit member is depressed, a corresponding upper contact is inserted into a corresponding partition plate opening. The lower wiring board is disposed under the partition plate, and has plural lower contacts corresponding to the plural upper contacts. The plural lower contacts and the plural upper contacts are collectively defined as the plural key intersections.

In an embodiment, the light-shading layer is disposed on a top surface of the upper wiring board, wherein the first side of the light-shading layer is thicker than the second side of the light-shading layer.

In an embodiment, the light-shading layer is made of white ink and disposed on a top surface of the upper wiring board, wherein the white ink at the first side of the light-shading layer is more concentrated than the white ink at the second side of the light-shading layer.

In an embodiment, the light-shading layer is composed of plural light-shading dots and disposed on a top surface of the upper wiring board, wherein the light-shading dots at the first side of the light-shading layer are more densely distributed than the light-shading dots at the second side of the light-shading layer.

In an embodiment, the light-shading layer is disposed on a top surface of the partition plate or a bottom surface of the partition plate, wherein the first side of the light-shading layer is thicker than the second side of the light-shading layer.

In an embodiment, the light-shading layer is made of white ink and disposed on a top surface of the partition plate or a bottom surface of the partition plate, wherein the white ink at the first side of the light-shading layer is more concentrated than the white ink at the second side of the light-shading layer.

In an embodiment, the light-shading layer is composed of plural light-shading dots and disposed on a top surface of the partition plate or a bottom surface of the partition plate, wherein the light-shading dots at the first side of the light-shading layer are more densely distributed than the light-shading dots at the second side of the light-shading layer.

In an embodiment, the illuminated keyboard further includes a light guide plate, which is stacked on the membrane switch circuit member and disposed under the membrane switch circuit member for guiding the plural light beams to the plural keys, wherein the light-shading layer is disposed on a top surface of the light guide plate, wherein the first side of the light-shading layer is thicker than the second side of the light-shading layer.

In an embodiment, the illuminated keyboard further includes a light guide plate, which is stacked on the membrane switch circuit member and disposed under the membrane switch circuit member for guiding the plural light beams to the plural keys, wherein the light-shading layer is made of white ink and disposed on a top surface of the light guide plate, wherein the white ink at the first side of the light-shading layer is more concentrated than the white ink at the second side of the light-shading layer.

In an embodiment, the illuminated keyboard further includes a light guide plate, which is stacked on the membrane switch circuit member and disposed under the membrane switch circuit member for guiding the plural light beams to the plural keys, wherein the light-shading layer is composed of plural light-shading dots and disposed on a top surface of the light guide plate, wherein the light-shading dots at the first side of the light-shading layer are more densely distributed than the light-shading dots at the second side of the light-shading layer.

In an embodiment, the illuminated keyboard further includes a main circuit board and a base plate. The main circuit board is connected with the membrane switch circuit member for providing first electric power to the membrane switch circuit member. The base plate is disposed under the illumination module for supporting the plural keys, the membrane switch circuit member, the illumination module and the main circuit board.

In an embodiment, the illumination module includes an illumination circuit board and plural light emitting diodes. The illumination circuit board is arranged at the first side of the membrane switch circuit member for providing second electric power. The plural light emitting diodes are mounted on the illumination circuit board for acquiring the second electric power, thereby emitting the plural light beams.

In an embodiment, the illuminated keyboard further includes a base plate for supporting the plural keys and the membrane switch circuit member. The base plate is connected with the plural keys. Each of the keys includes a keycap, a scissors-type connecting element and an elastic element. The keycap includes a light-transmissible region. The scissors-type connecting element is arranged between the base plate and the keycap for connecting the base plate and the keycap, and allowing the keycap to be moved upwardly and downwardly with respect to the base plate. The elastic element is arranged between the membrane switch circuit member and the keycap. When the keycap is pressed, the elastic element is compressed to push against the membrane switch circuit member, so that a corresponding upper contact is contacted with a corresponding lower contact. Whereas, when a depressing force exerted on the keycap is eliminated, an elastic force provided by the elastic element is acted on the keycap, so that the keycap is returned to an original position.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic top view illustrating the outward appearance of a conventional keyboard;

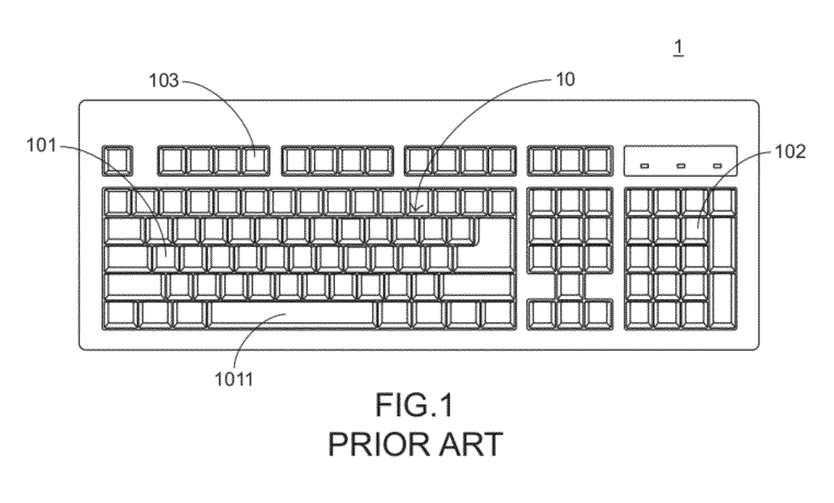

FIG. 2 is a schematic cross-sectional view illustrating a conventional illuminated keyboard;

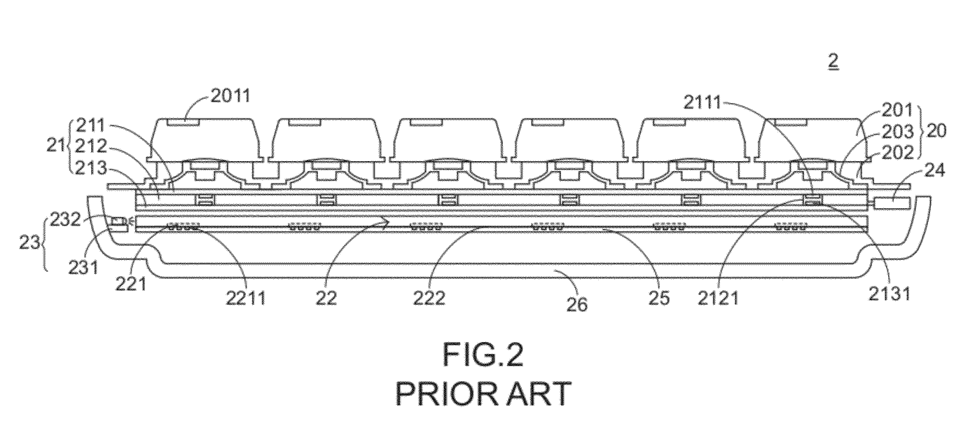

FIG. 3 is a schematic cross-sectional view illustrating an illuminated keyboard according to a first embodiment of the present invention;

FIG. 4 is a schematic exploded view illustrating the membrane switch circuit member and the illumination module of the illuminated keyboard according to the first embodiment of the present invention;

FIG. 5 is a schematic cross-sectional view illustrating an illuminated keyboard according to a second embodiment of the present invention;

FIG. 6 is a schematic exploded view illustrating the membrane switch circuit member and the illumination module of the illuminated keyboard according to the second embodiment of the present invention;

FIG. 7 is a schematic cross-sectional view illustrating an illuminated keyboard according to a third embodiment of the present invention;

FIG. 8 is a schematic cross-sectional view illustrating an illuminated keyboard according to a fourth embodiment of the present invention; and

FIG. 9 is a schematic exploded view illustrating the membrane switch circuit member, the light guide plate and the illumination module of the illuminated keyboard according to the fourth embodiment of the present invention.

### DETAILED DESCRIPTION OF THE PREFERRED EMBODIMENT

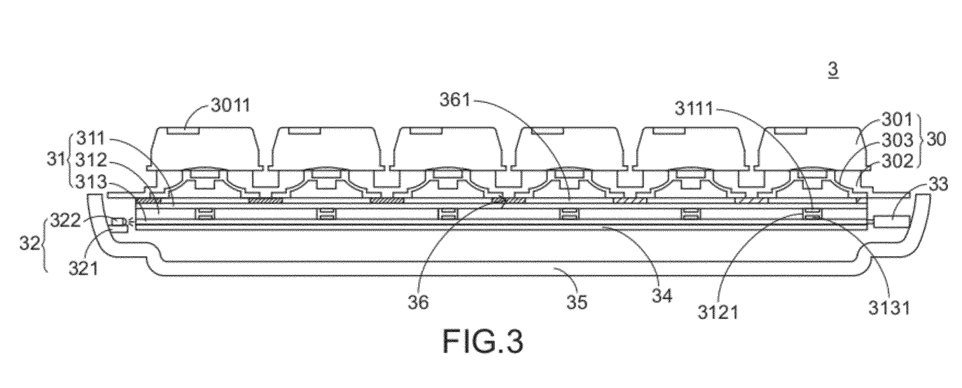

For obviating the drawbacks encountered from the prior art, the present invention provides illuminated keyboard. FIG. 3 is a schematic cross-sectional view illustrating an illuminated keyboard according to a first embodiment of the present invention. As shown in FIG. 3, the illuminated keyboard 3 comprises plural keys 30, a membrane switch circuit member 31, an illumination module 32, a main circuit board 33, a reflector 34, a base plate 35 and a light-shading layer 36. The key 30 comprises a keycap 301, a key housing 302 and an elastic element 303. From top to bottom, the keycap 301, the key housing 302, the elastic element 303, the light-shading layer 36, the membrane switch circuit member 31, the reflector 34 and the base plate 35 of the illuminated keyboard 3 are sequentially shown. The illumination module 32 is arranged at a first side of the membrane switch circuit member 31. The main circuit board 33 is arranged at a second side of the membrane switch circuit member 31. In this embodiment, the illuminated keyboard 3 is a keyboard for a desktop computer. The first side of the membrane switch circuit member 31 denotes the side of the illuminated keyboard 3 having the space bar. The second side of the membrane switch circuit member 31 denotes the side of the illuminated keyboard 3 having the function key F1.

In the key 30, the keycap 301 is exposed outside the surface of the illuminated keyboard 3, so that the keycap 301 can be depressed by the user. In addition, the keycap 301 has a light-transmissible region 3011. The light-transmissible region 3011 is located at a character region or a symbol region of the keycap 301. The key housing 302 is used for fixing the keycap 301 and the elastic element 303. The elastic element 303 is penetrated through the key housing 302. In addition, both ends of the elastic element 303 are contacted with the keycap 301 and the membrane switch circuit member 31, respectively. In this embodiment, the elastic element 303 is made of a transparent rubbery material. Moreover, the membrane switch circuit member 31 is connected with the main circuit board 33 for transmitting first electric power and signals.

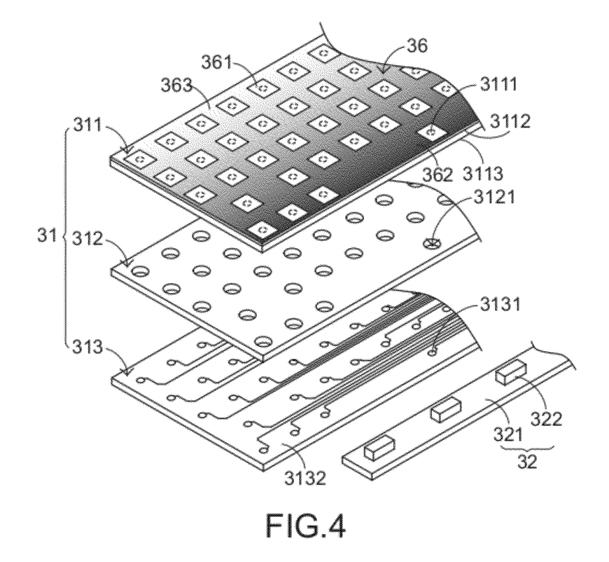

FIG. 4 is a schematic exploded view illustrating the membrane switch circuit member and the illumination module of the illuminated keyboard according to the first embodiment of the present invention. Please refer to FIGS. 3 and 4. The illumination module 32 comprises an illumination circuit board 321 and plural light emitting diodes 322. The illumination circuit board 321 is arranged at the first side of the membrane switch circuit member 31 for providing second electric power to the plural light emitting diodes 322. The plural light emitting diodes 322 are mounted on the illumination circuit board 321. By acquiring the second electric power, the plural light emitting diodes 322 are enabled to emit plural light beams. In this embodiment, the plural light emitting diodes 322 are side-view light emitting diodes. The membrane switch circuit member 31 comprises an upper wiring board 311, a partition plate 312 and a lower wiring board 313. The upper wiring board 311 has plural upper contacts 3111. The plural upper contacts 3111 are formed on a bottom surface 3113 of the upper wiring board 311. The partition plate 312 is disposed under the upper wiring board 311, and comprises plural partition plate openings 3121 corresponding to the plural upper contacts 3111. The lower wiring board 313 is disposed under the partition plate 312, and comprises plural lower contacts 3131 corresponding to the plural upper contacts 3111. The plural lower contacts 3131 and the plural upper contacts 3111 are collectively defined as plural key intersections. The plural lower contacts 3131 are formed on a top surface 3132 of the lower wiring board 313. In this embodiment, the upper wiring board 311 and the partition plate 312 are made of a transparent material such as polycarbonate (PC) or polyethylene (PE). Whereas, the lower wiring board 313 is made of a light-guiding material such as polycarbonate (PC) or polymethylmethacrylate (PMMA).

Please refer to FIGS. 3 and 4 again. The light-shading layer 36 is disposed on a top surface 3112 of the upper wiring board 311 for sheltering the plural light beams. In this embodiment, the light-shading layer 36 is a white ink layer. As shown in FIG. 4, the light-shading layer 36 further comprises plural perforations 361. Due to the perforations 361, the plural upper contacts 3111 are kept away from the light-shading layer 36. The use of the light-shading layer 36 has at least two purposes. The first purpose of the light-shading layer 36 is to avoid leakage of the light beams from the region between any two adjacent keycaps 301. The second purpose of the light-shading layer 36 is to allow the light beams to be transmitted to the light-transmissible regions 3011 of the keycaps 301 through the perforations 361. As shown in FIG. 3, the reflector 34 is disposed under the membrane switch circuit member 31 for reflecting the light beams. The base plate 35 is disposed under the reflector 34 for supporting the keycap 301, the key housing 302, the elastic element 303, the membrane switch circuit member 31 and the reflector 34.

After the above components are combined together, the illuminated keyboard 3 is assembled. When the keycap 301 is depressed by a user, the keycap 301 is moved downwardly with respect to the key housing 302. At the same time, the elastic element 303 is compressed to push against the membrane switch circuit member 31, so that the upper contact 3111 is inserted into a corresponding partition plate opening 3121 to be contacted with a corresponding lower contact 3131. Under this circumstance, a corresponding key intersection of the membrane switch circuit member 31 is triggered to generate a key signal. Whereas, when the depressing force exerted on the key 301 is eliminated, an elastic force provided by the elastic element 303 is acted on the keycap 301. Due to the elastic force, the keycap 301 is returned to its original position. Since the lower wiring board 313 is made of a light-guiding material, after the plural light beams emitted by the plural light emitting diodes 322 of the illumination module 32 are directed to the lower wiring board 313 of the membrane switch circuit member 31, some of the light beams are guided to the light-transmissible regions 3011 of the keycaps 301 by the lower wiring board 313. At the same time, some of the light beams are reflected by the reflector 34 under the membrane switch circuit member 31, and the reflected light beams are directed to the lower wiring board 313 again to be guided by the lower wiring board 313.

A process of forming the light-shading layer 36 will be illustrated as follows. Firstly, a stencil with plural rectangular shading zones are placed on the top surface 3112 of the upper wiring board 311 of the membrane switch circuit member 31, wherein the plural rectangular shading zones are respectively aligned with the plural upper contacts 3111 of the upper wiring board 311. Then, white ink is poured to the stencil such that the top surface 3112 of the upper wiring board 311 is coated with the white ink. Since the white ink is blocked by the plural rectangular shading zones of the stencil, the plural perforations 361 of the light-shading layer 36 are formed at the positions corresponding to the plural rectangular shading zones. Afterwards, the white ink is subject to a screen printing process, so that the white ink is printed on the top surface 3112 of the upper wiring board 311 to produce the light-shading layer 36. In this embodiment, the white ink for producing the light-shading layer 36 is UV-curable white ink.

More specially, for producing the light-shading layer 36, two stencils are respectively placed on a first side 362 and a second side 363 of the upper wiring board 311. After the screen printing process is performed, the light-shading layer 36 with a non-uniform concentration profile is produced. In this embodiment, the concentration of the white ink overlying the first side of the membrane switch circuit member 31 is relatively higher, and the white ink overlying the second side of the membrane switch circuit member 31 is relatively lower. In such way, the first side 362 of the light-shading layer 36, which is closer to the illumination module 32, has a higher light-shading percentage than the second side 363 of the light-shading layer 36. Therefore, the keys 30 of the illuminated keyboard 3 can be uniformly illuminated.

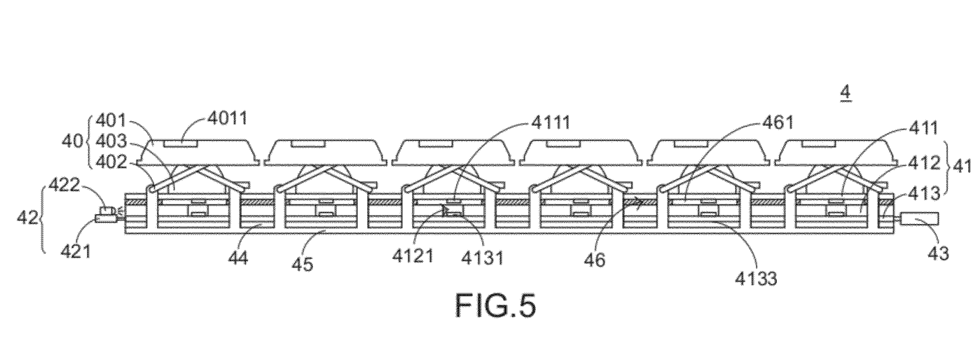

The present invention further provides an illuminated keyboard of a second embodiment. FIG. 5 is a schematic cross-sectional view illustrating an illuminated keyboard according to a second embodiment of the present invention. As shown in FIG. 4, the illuminated keyboard 4 comprises plural keys 40, a membrane switch circuit member 41, an illumination module 42, a main circuit board 43, a reflector 44, a base plate 45 and a light-shading layer 46. The key 40 comprises a keycap 401, a scissors-type connecting element 402 and an elastic element 403. The membrane switch circuit member 41 comprises an upper wiring board 411, a partition plate 412 and a lower wiring board 413. From top to bottom, the keycap 401, the scissors-type connecting element 402, the elastic element 403, the upper wiring board 411, the light-shading layer 46, the partition plate 412, the lower wiring board 413, the reflector 44 and the base plate 45 of the illuminated keyboard 4 are sequentially shown. The illumination module 42 is arranged at a first side of the membrane switch circuit member 41. The main circuit board 43 is arranged at a second side of the membrane switch circuit member 41. In this embodiment, the illuminated keyboard 4 is a keyboard for a notebook computer. The first side of the membrane switch circuit member 41 denotes the front side of the membrane switch circuit member 41, i.e. the side of the illuminated keyboard 4 having the space bar. The second side of the membrane switch circuit member 41 denotes the rear side of the membrane switch circuit member 41, i.e. the side of the illuminated keyboard 4 having the function key F1.

In the key 40, the keycap 401 is exposed outside the surface of the illuminated keyboard 4, so that the keycap 401 can be depressed by the user. In addition, the keycap 401 has a light-transmissible region 4011. The light-transmissible region 4011 is located at a character region or a symbol region of the keycap 401. The scissors-type connecting element 402 is connected with the keycap 401 and the base plate 45. The elastic element 403 is penetrated through the scissors-type connecting element 402. In addition, both ends of the elastic element 403 are contacted with the keycap 401 and the membrane switch circuit member 41, respectively. Moreover, the membrane switch circuit member 41 is connected with the main circuit board 43 for transmitting first electric power and signals.

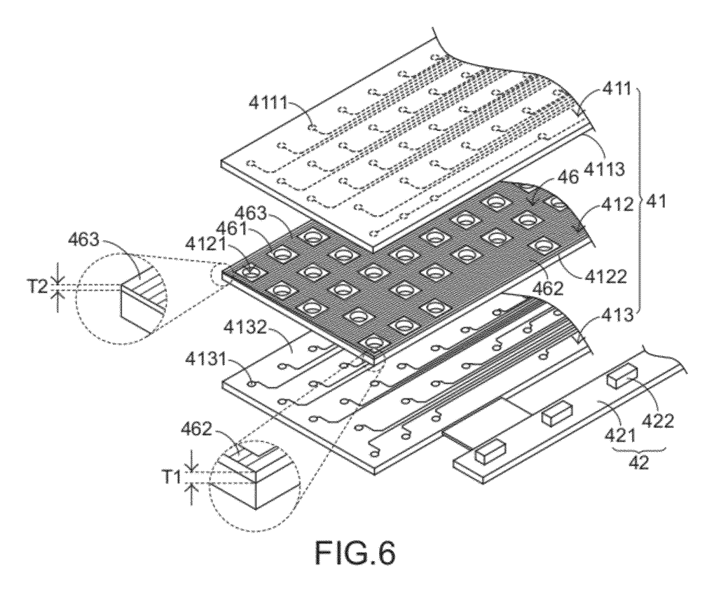

FIG. 6 is a schematic exploded view illustrating the membrane switch circuit member and the illumination module of the illuminated keyboard according to the second embodiment of the present invention. The illumination module 42 comprises an illumination circuit board 421 and plural light emitting diodes 422. The illumination circuit board 421 is arranged at the first side of the membrane switch circuit member 41 for providing second electric power to the plural light emitting diodes 422. The plural light emitting diodes 422 are mounted on the illumination circuit board 421. By acquiring the second electric power, the plural light emitting diodes 422 are enabled to emit plural light beams. In this embodiment, the plural light emitting diodes 422 are side-view light emitting diodes. In this embodiment, the illumination circuit board 421 is a flexible printed circuit (FPC) board. In the membrane switch circuit member 41, the upper wiring board 411 has plural upper contacts 4111, and the plural upper contacts 4111 are formed on a bottom surface 4113 of the upper wiring board 411. The partition plate 412 is disposed under the upper wiring board 411, and comprises plural partition plate openings 4121 corresponding to the plural upper contacts 4111. The lower wiring board 413 is disposed under the partition plate 412, and comprises plural lower contacts 4131 corresponding to the plural upper contacts 4111. The plural lower contacts 4131 are formed on a top surface 4132 of the lower wiring board 413. The plural lower contacts 4131 and the plural upper contacts 4111 are collectively defined as plural key intersections. In this embodiment, the upper wiring board 411 and the partition plate 412 are made of a transparent material such as polycarbonate (PC) or polyethylene (PE). Whereas, the lower wiring board 413 is made of a light-guiding material such as polycarbonate (PC) or polymethylmethacrylate (PMMA).

Please refer to FIGS. 5 and 6 again. The light-shading layer 46 is disposed on a top surface 4122 of the partition plate 412 for sheltering the light beams. As shown in FIG. 6, the light-shading layer 46 further comprises plural perforations 461. Due to the perforations 461, the plural upper contacts 4111 are kept away from the light-shading layer 46. The use of the light-shading layer 46 has at least two purposes. The first purpose of the light-shading layer 46 is to avoid leakage of the light beams from the region between any two adjacent keycaps 401. The second purpose of the light-shading layer 46 is to allow the light beams to be transmitted to the light-transmissible regions 4011 of the keycaps 401 through the perforations 461. As shown in FIG. 5, the reflector 44 is disposed under the membrane switch circuit member 41 for reflecting the plural light beams. The base plate 45 is disposed under the reflector 44 and connected with the scissors-type connecting element 402. The base plate 45 is used for supporting the keycap 401, the scissors-type connecting element 402, the elastic element 403, the membrane switch circuit member 41 and the reflector 44. The operations of the illuminated keyboard 4 of this embodiment are similar to those illustrated in the first embodiment, and are not redundantly described herein.

A process of forming the light-shading layer 46 will be illustrated as follows. Firstly, a stencil with plural rectangular shading zones are placed on the top surface 4122 of the partition plate 412 of the membrane switch circuit member 41, wherein the plural rectangular shading zones are respectively aligned with the plural partition plate openings 4121 of the partition plate 412. Then, white ink is poured to the stencil such that the top surface 4122 of the partition plate 412 is coated with the white ink. Since the white ink is blocked by the plural rectangular shading zones of the stencil, the plural perforations 461 of the light-shading layer 46 are formed at the positions corresponding to the plural rectangular shading zones. Afterwards, the white ink is subject to a screen printing process, so that the white ink is printed on the top surface 4122 of the partition plate 412 to produce the light-shading layer 46.

More specially, for producing the light-shading layer 46, one side of the membrane switch circuit member 41 is subject to a single screen printing step, but the other side of the membrane switch circuit member 41 is subject to multiple screen printing steps. Consequently, the light-shading layer 46 with a non-uniform thickness profile is produced. In this embodiment, as shown in FIG. 6, the thickness T1 of the white ink overlying the first side of the membrane switch circuit member 41 is relatively higher, and the thickness T2 of the white ink overlying the second side of the membrane switch circuit member 41 is lower than the thickness T1. In such way, the first side 462 of the light-shading layer 46, which is closer to the illumination module 42, has a higher light-shading percentage than the second side 463 of the light-shading layer 46. Therefore, the keys 40 of the illuminated keyboard 4 can be uniformly illuminated.

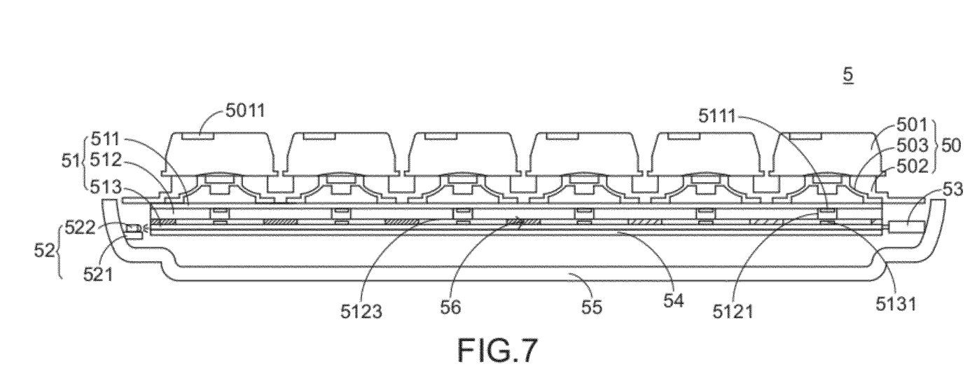

The present invention further provides an illuminated keyboard of a third embodiment. FIG. 7 is a schematic cross-sectional view illustrating an illuminated keyboard according to a third embodiment of the present invention. As shown in FIG. 7, the illuminated keyboard 5 comprises plural keys 50, a membrane switch circuit member 51, an illumination module 52, a main circuit board 53, a reflector 54, a base plate 55 and a light-shading layer 56. The key 50 comprises a keycap 501, a scissors-type connecting element 502 and an elastic element 503. The membrane switch circuit member 51 comprises an upper wiring board 511, a partition plate 512 and a lower wiring board 513. From top to bottom, the keycap 501, the scissors-type connecting element 502, the elastic element 503, the upper wiring board 511, the partition plate 512, the light-shading layer 56, the lower wiring board 513, the reflector 54 and the base plate 55 of the illuminated keyboard 5 are sequentially shown. The illumination module 52 is arranged at a first side of the membrane switch circuit member 51. The main circuit board 53 is arranged at a second side of the membrane switch circuit member 51.

In this embodiment, the illuminated keyboard 5 is a keyboard for a desktop computer. In comparison with the illuminated keyboard 3 of the first embodiment, the light-shading layer 56 of the illuminated keyboard 5 of this embodiment is formed on a bottom surface 5123 of the partition plate 512 of the membrane switch circuit member 51. The other components of the illuminated keyboard 5 are similar to those illustrated in the first embodiment, and are not redundantly described herein.

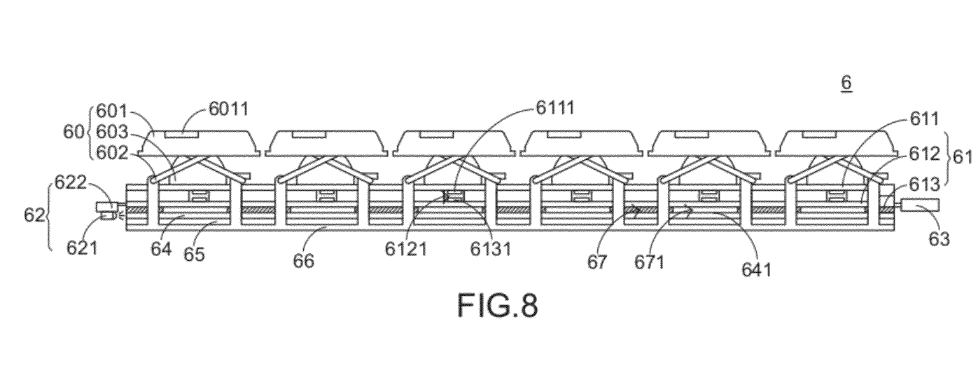

The present invention further provides an illuminated keyboard of a fourth embodiment. FIG. 8 is a schematic cross-sectional view illustrating an illuminated keyboard according to a fourth embodiment of the present invention. As shown in FIG. 8, the illuminated keyboard 6 comprises plural keys 60, a membrane switch circuit member 61, an illumination module 62, a main circuit board 63, a light guide plate 64, a reflector 65, a base plate 66 and a light-shading layer 67. From top to bottom, the keycap 601, the scissors-type connecting element 602, the elastic element 603, the membrane switch circuit member 61, the light-shading layer 67, the light guide plate 64, the reflector 65 and the base plate 66 of the illuminated keyboard 6 are sequentially shown. The illumination module 62 is arranged at a first side of the membrane switch circuit member 61. The main circuit board 63 is arranged at a second side of the membrane switch circuit member 61. In this embodiment, the illuminated keyboard 6 is a keyboard for a notebook computer. The first side of the membrane switch circuit member 61 denotes the front side of the membrane switch circuit member 61, i.e. the side of the illuminated keyboard 6 having the space bar. The second side of the membrane switch circuit member 61 denotes the rear side of the membrane switch circuit member 61, i.e. the side of the illuminated keyboard 6 having the function key F1.

In the key 60, the keycap 601 is exposed outside the surface of the illuminated keyboard 6, so that the keycap 601 can be depressed by the user. In addition, the keycap 601 has a light-transmissible region 6011. The light-transmissible region 6011 is located at a character region or a symbol region of the keycap 601. The scissors-type connecting element 602 is connected with the keycap 601 and the base plate 66. The elastic element 603 is penetrated through the scissors-type connecting element 602. In addition, both ends of the elastic element 603 are contacted with the keycap 601 and the membrane switch circuit member 61, respectively. Moreover, the membrane switch circuit member 61 is connected with the main circuit board 63 for transmitting first electric power and signals.

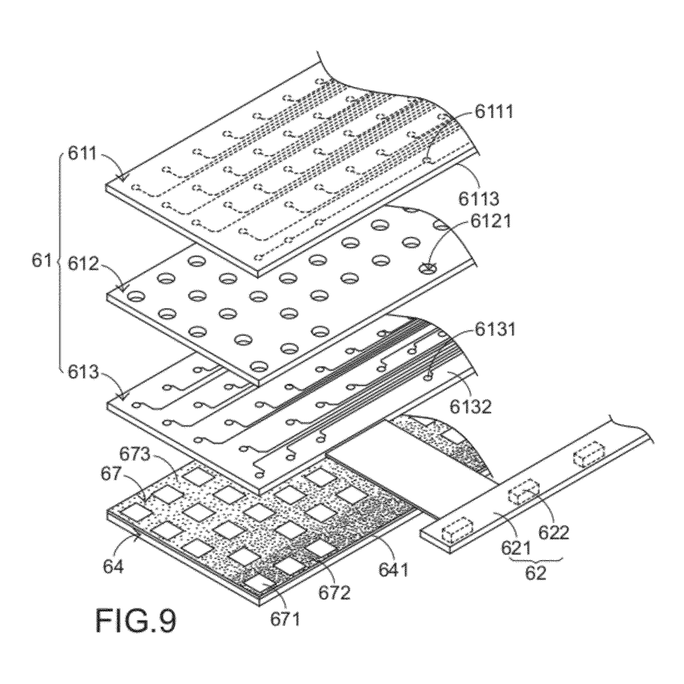

FIG. 9 is a schematic exploded view illustrating the membrane switch circuit member, the light guide plate and the illumination module of the illuminated keyboard according to the fourth embodiment of the present invention. The membrane switch circuit member 61 comprises an upper wiring board 611, a partition plate 612 and a lower wiring board 613. The upper wiring board 611 has plural upper contacts 6111. The plural upper contacts 6111 are formed on a bottom surface 6113 of the upper wiring board 611. The partition plate 612 is disposed under the upper wiring board 611, and comprises plural partition plate openings 6121 corresponding to the plural upper contacts 6111. The lower wiring board 613 is disposed under the partition plate 612, and comprises plural lower contacts 6131 corresponding to the plural upper contacts 6111. The plural lower contacts 6131 and the plural upper contacts 6111 are collectively defined as plural key intersections. The plural lower contacts 6131 are formed on a top surface 6132 of the lower wiring board 613. In this embodiment, the upper wiring board 611, the partition plate 612 and the lower wiring board 613 are made of a transparent material such as polycarbonate (PC) or polyethylene (PE).

The illumination module 62 comprises an illumination circuit board 621 and plural light emitting diodes 622. The illumination circuit board 621 is arranged at the first side of the membrane switch circuit member 61 for providing second electric power to the plural light emitting diodes 622. The plural light emitting diodes 622 are mounted on the illumination circuit board 621. By acquiring the second electric power, the plural light emitting diodes 622 are enabled to emit plural light beams. In this embodiment, the plural light emitting diodes 622 are side-view light emitting diodes. As shown in FIG. 8, the reflector 65 is disposed under the membrane switch circuit member 61 for reflecting the light beams. The light guide plate 64 is stacked on the membrane switch circuit member 61 and disposed under the membrane switch circuit member 61. By the light guide plate 64, the plural light beams are guided to the plural keys 60. The base plate 66 is disposed under the reflector 65 and connected with the scissors-type connecting element 602. The base plate 66 is used for supporting the keycap 601, the scissors-type connecting element 602, the elastic element 603, the membrane switch circuit member 61, the light guide plate 64 and the reflector 65.

Please refer to FIG. 9 again. The light-shading layer 67 is disposed on a top surface 641 of the light guide plate 64 for sheltering the plural light beams. In this embodiment, the light-shading layer 67 is composed of plural light-shading dots, which are made of white ink. Moreover, the light-shading dots of the light-shading layer 67 are not uniformly distributed. In this embodiment, the light-shading dots of the light-shading layer 67 overlying the first side of the light guide plate 64 are more densely distributed, so that the light-shading percentage is relatively higher. Whereas, the light-shading dots of the light-shading layer 67 overlying the second side of the light guide plate 64 are less densely distributed, so that the light-shading percentage is relatively lower. In such way, the first side 672 of the light-shading layer 67, which is closer to the illumination module 62, has a higher light-shading percentage than the second side 673 of the light-shading layer 67. Therefore, the keys 60 of the illuminated keyboard 6 can be uniformly illuminated.

From the above description, the illuminated keyboard of the present invention has a light-shading layer with at least two light-shading percentages. The portion of the light-shading layer with a higher light-shading percentage is closer to the illumination module than the portion of the light-shading layer with a lower light-shading percentage. As a consequence, the keys of the illuminated keyboard can be uniformly illuminated.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An illuminated keyboard, comprising:
plural keys;
a membrane switch circuit member having plural key intersections corresponding to respective keys;
an illumination module arranged at a first side of said membrane switch circuit member for emitting plural light beams; and
a light-shading layer disposed under said plural keys for sheltering said plural light beams, wherein a first side of said light-shading layer has a higher light-shading percentage than a second side of said light-shading layer, and said first side of said light-shading layer is closer to said illumination module than said second side of said light-shading layer.

2. The illuminated keyboard according to claim 1 wherein said membrane switch circuit member comprises:
an upper wiring board having plural upper contacts;
a partition plate disposed under said upper wiring board, and having plural partition plate openings corresponding to said plural upper contacts, wherein when said membrane switch circuit member is depressed, a corresponding upper contact is inserted into a corresponding partition plate opening; and
a lower wiring board disposed under said partition plate, and having plural lower contacts corresponding to said plural upper contacts, wherein said plural lower contacts and said plural upper contacts are collectively defined as said plural key intersections.

3. The illuminated keyboard according to claim 2 wherein said light-shading layer is disposed on a top surface of said upper wiring board, wherein said first side of said light-shading layer is thicker than said second side of said light-shading layer.

4. The illuminated keyboard according to claim 2 wherein said light-shading layer is made of white ink and disposed on a top surface of said upper wiring board, wherein said white ink at said first side of said light-shading layer is more concentrated than said white ink at said second side of said light-shading layer.

5. The illuminated keyboard according to claim 2 wherein said light-shading layer is composed of plural light-shading dots and disposed on a top surface of said upper wiring board, wherein said light-shading dots at said first side of said light-shading layer are more densely distributed than said light-shading dots at said second side of said light-shading layer.

6. The illuminated keyboard according to claim 2 wherein said light-shading layer is disposed on a top surface of said partition plate or a bottom surface of said partition plate, wherein said first side of said light-shading layer is thicker than said second side of said light-shading layer.

7. The illuminated keyboard according to claim 2 wherein said light-shading layer is made of white ink and disposed on a top surface of said partition plate or a bottom surface of said partition plate, wherein said white ink at said first side of said light-shading layer is more concentrated than said white ink at said second side of said light-shading layer.

8. The illuminated keyboard according to claim 2 wherein said light-shading layer is composed of plural light-shading dots and disposed on a top surface of said partition plate or a bottom surface of said partition plate, wherein said light-shading dots at said first side of said light-shading layer are more densely distributed than said light-shading dots at said second side of said light-shading layer.

9. The illuminated keyboard according to claim 1 further comprising a light guide plate, which is stacked on said membrane switch circuit member and disposed under said membrane switch circuit member for guiding said plural light beams to said plural keys, wherein said light-shading layer is disposed on a top surface of said light guide plate, wherein said first side of said light-shading layer is thicker than said second side of said light-shading layer.

10. The illuminated keyboard according to claim 1 further comprising a light guide plate, which is stacked on said membrane switch circuit member and disposed under said membrane switch circuit member for guiding said plural light beams to said plural keys, wherein said light-shading layer is made of white ink and disposed on a top surface of said light guide plate, wherein said white ink at said first side of said light-shading layer is more concentrated than said white ink at said second side of said light-shading layer.

11. The illuminated keyboard according to claim 1 further comprising a light guide plate, which is stacked on said membrane switch circuit member and disposed under said membrane switch circuit member for guiding said plural light beams to said plural keys, wherein said light-shading layer is composed of plural light-shading dots and disposed on a top surface of said light guide plate, wherein said light-shading dots at said first side of said light-shading layer are more densely distributed than said light-shading dots at said second side of said light-shading layer.

12. The illuminated keyboard according to claim 1 further comprising:
a main circuit board connected with said membrane switch circuit member for providing first electric power to said membrane switch circuit member; and
a base plate disposed under said membrane switch circuit member for supporting said plural keys, said membrane switch circuit member, said illumination module and said main circuit board.

13. The illuminated keyboard according to claim 1 wherein said illumination module comprises:
an illumination circuit board arranged at said first side of said membrane switch circuit member for providing second electric power; and
plural light emitting diodes mounted on the illumination circuit board for acquiring said second electric power, thereby emitting said plural light beams.

14. The illuminated keyboard according to claim 1 further comprising a base plate for supporting said plural keys and said membrane switch circuit member, wherein said base plate is connected with said plural keys, and each of said keys comprises:
a keycap comprising a light-transmissible region;
a scissors-type connecting element arranged between said base plate and said keycap for connecting said base plate and said keycap, and allowing said keycap to be moved upwardly and downwardly with respect to said base plate; and
an elastic element arranged between said membrane switch circuit member and said keycap, wherein when said keycap is pressed, said elastic element is compressed to push against said membrane switch circuit member, so that a corresponding upper contact is contacted with a corresponding lower contact, wherein when a depressing force exerted on said keycap is eliminated, an elastic force provided by said elastic element is acted on said keycap, so that said keycap is returned to an original position.
